(19) United States
(12) Patent Application Publication
(10) Pub. No.: US 2026/0371867 A1
(43) Pub. Date: Nov. 19, 2026

(54) DISPLAY DEVICE AND METHOD FOR MANUFACTURING SAME

(71) Applicant: Sharp Display Technology Corporation, Kameyama City, Mie (JP)

(72) Inventors: Hiroshi OGITA, Kameyama City, Mie (JP); Motoji SHIOTA, Kameyama City, Mie (JP); Hiroki KAWAMURA, Kameyama City, Mie (JP); Yuhichiroh KATSUMA, Kameyama City, Mie (JP); Yohji TOYOTA, Kameyama City, Mie (JP); Yasuo IWASAKI, Kameyama City, Mie (JP); Kazuki NAKASHIMA, Kameyama City, Mie (JP)

(21) Appl. No.: 19/149,644

(22) PCT Filed: Jan. 24, 2023
(86) PCT No.: PCT/JP2023/002029

§ 371 Date: Jul. 21, 2025

(51) Int. Cl. H10K 59/131; H10K 59/12; H10K 59/124; H10K 59/80; H10K 102/00

(52) U.S. Cl. CPC H10K 59/131; H10K 59/1201; H10K 59/124; H10K 59/871; H10K 2102/311

(57) ABSTRACT

A display panel has a folding portion provided in a picture-frame region between a terminal unit and a display region and extending in a second direction perpendicular to a first direction. The display panel has a back face provided with a film and a back face slit shaped into a strip shape, provided to the film to overlap with the folding portion in a plan view, and extending to opposing end portions of the picture-frame region in the second direction. Opposing end portions of the back face slit in the second direction are provided with a pair of narrow width portions each having a width narrower than a width in the first direction of an intermediate portion in the second direction.

### TECHNICAL FIELD

The present invention relates to a display device and a method for manufacturing the display device.

### BACKGROUND ART

In recent years, light-emitting organic electroluminescent (EL) display devices using organic EL elements have attracted attention as a replacement for liquid crystal display devices. These organic EL display devices include flexible organic EL display devices. A proposed flexible display device has organic EL elements formed on a flexible resin substrate. Here, an organic EL display device includes, for example, a picture-frame region provided around a display region that displays an image. Such an organic EL display device is desired to have the picture-frame region narrowed so that the picture-frame region occupies a smaller area in a plan view. Hence, a proposal is made for a flexible organic EL display device; that is, for example, folding to narrow a picture-frame region provided toward a terminal unit and having a plurality of terminals arranged thereto.

For example, Patent Document 1 proposes a flexible wiring board for driving input of a flat display device. The flexible wiring board is formed of a flexible base film and a lead pattern formed on the base film. The flexible wiring board is provided with a folding thick portion. As the flexible wiring board is folded at this folding thick portion, the folding thick portion is folded. This flexible wiring board has the folding thick portion coated with resin so that the folding thick portion is formed to have a convex shape.

### CITATION LIST

### Patent Literature

[Patent Document 1] Japanese Unexamined Patent Application Publication No. 2002-141620

### SUMMARY OF INVENTION

### Technical Problems

As to a flexible organic EL display device having a foldable folding portion in a picture-frame region, a structure is proposed as follows: a film is attached to a face coming inwards when the folding portion is folded (i.e., a back face of a display panel included in the device), and a portion included in the film and disposed to the folding portion toward the terminal unit is removed into a shape of a slit by, for example, laser-slitting processing.

The flexible organic EL display device having the above structure is usually subjected to such steps as: the laser-slitting processing given to the portion of the film, laser-cutting processing (outline processing) given to the display panel so that an outline of the display panel is shaped into a desired shape, and folding processing given to the folding portion toward the terminal unit so that the folding portion serves as an axis. As to the steps, in the conventional structure, a cross-section of a portion cut and processed with the laser is used to be straight (flat). However, as the display panel (a display portion) has a narrower picture-frame region, the cross-section becomes rounded, and the folding portion (a slit portion) comes closer to the display region. In the resulting structure, a rounded portion in a base of the terminal unit and the slit-processed portion inevitably overlap with each other.

The above structure exhibits poor strength in the vicinity of the rounded portion in the base of the terminal unit, and readily transmits force created in various kinds of processing and folding work. Hence, tensile stress in a thickness direction of the display panel is applied to a constriction of the rounded portion in the base of the terminal unit. The tensile stress causes a crack in a resin substrate (in a vicinity of the rounded portion of the terminal unit) of the display panel, which might induce a break in a wire. Thus, the above structure has room for improvement.

The present invention is conceived in view of the above problems and sets out to reduce a break caused in a wire of a terminal unit in a picture-frame region when the picture-frame region is formed narrow.

### Solution to Problems

In order to achieve the above object, a display device according to the present invention includes: a display panel having a display region, a picture-frame region provided around the display region, a terminal unit provided to one end portion of the picture-frame region in a first direction, and a folding portion provided in the picture-frame region between the terminal unit and the display region, and extending in a second direction perpendicular to the first direction; a film provided to a back face of the display panel and covering the back face; and a back face slit shaped into a strip shape, provided to the film to overlap with the folding portion in a plan view, and extending to opposing end portions of the picture-frame region in the second direction. Opposing end portions of the back face slit in the second direction are provided with a pair of narrow width portions each having a width narrower than a width in the first direction of an intermediate portion in the second direction.

As to a display device including: a display panel having a display region, a picture-frame region provided around the display region, a terminal unit provided to one end portion of the picture-frame region in a first direction, and a folding portion provided in the picture-frame region between the terminal unit and the display region, and extending in a second direction perpendicular to the first direction; a film provided to a back face of the display panel and covering the back surface; and a back face slit shaped into a strip shape, provided to the film to overlap with the folding portion in a plan view, and extending to opposing end portions of the picture-frame region in the second direction, a method for manufacturing the display device according to the present invention includes: a film attaching step of attaching the film to the back face of the display panel; and after the film attaching step, a back-face-slit forming step of forming the back face slit by emitting a laser beam twice or more to the film in the folding portion in parallel with the second direction. At the back-face-slit forming step, an emission distance or an emission time of the laser beam in the second direction is changed so that opposing end portions of the back face slit in the second direction are provided with a pair of narrow width portions each having a width narrower than a width in the first direction of an intermediate portion in the second direction.

### Advantageous Effect of Invention

The present invention can reduce a break caused in a wire of a terminal unit in a picture-frame region when the picture-frame region is formed narrow.

### BRIEF DESCRIPTION OF DRAWINGS

FIG. 1 is a plan view of a schematic configuration of a front face of a display panel in an organic EL display device according to a first embodiment of the present invention.

FIG. 2 is a plan view of a detailed configuration of a display region of the organic EL display device according to the first embodiment of the present invention.

FIG. 3 is a plan view of a back face (a face coming inwards when folded) of the display panel in a picture-frame region of the organic EL display device according to the first embodiment of the present invention.

FIG. 4 is a cross-sectional view of a folding portion in picture-frame region of the organic EL display device according to the first embodiment of the present invention. The cross-sectional view is taken along line IV-IV in FIG. 3.

FIG. 5 is a cross-sectional view of the picture-frame region of the organic EL display device according to the first embodiment of the present invention. The cross-sectional view is taken along line V-V in FIG. 3.

FIG. 6 is a cross-sectional view of the picture-frame region of the organic EL display device according to the first embodiment of the present invention. The cross-sectional view is taken along a line VI-VI in FIG. 3.

FIG. 7 is a cross-sectional view of the organic EL display device in a folding state according to the first embodiment of the present invention. The cross-sectional view is taken along line V-V in FIG. 3.

FIG. 8 is a cross-sectional view of the display region of the organic EL display device according to the first embodiment of the present invention.

FIG. 9 is an equivalent circuit diagram illustrating a pixel circuit of the organic EL display device according to the first embodiment of the present invention.

FIG. 10 is a cross-sectional view of an organic EL layer included in the organic EL display device according to the first embodiment of the present invention.

FIG. 11 is a perspective view of an example of a back-face-slit forming step in a method for manufacturing the organic EL display device according to the first embodiment of the present invention.

FIG. 12 is a perspective view of an example of a panel outline processing step in the method for manufacturing the organic EL display device according to the first embodiment of the present invention.

FIG. 13 is a plan view of a back face (a face coming inwards when folded) of the display panel in the picture-frame region of an organic EL display device according to a second embodiment of the present invention. FIG. 13 corresponds to FIG. 3.

### DESCRIPTION OF EMBODIMENTS

Embodiments of the present invention will be described in detail below with reference to the drawings. Note that the present invention shall not be limited to the embodiments below.

### First Embodiment

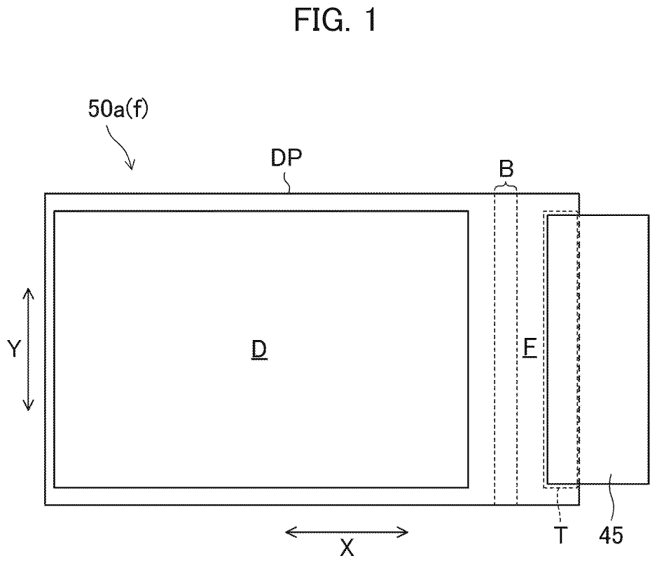

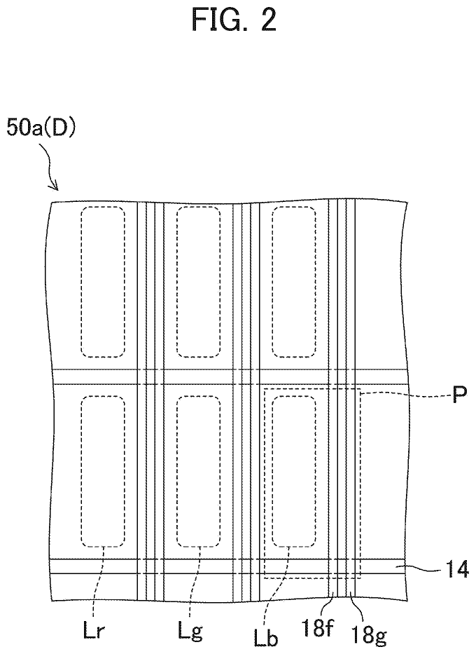

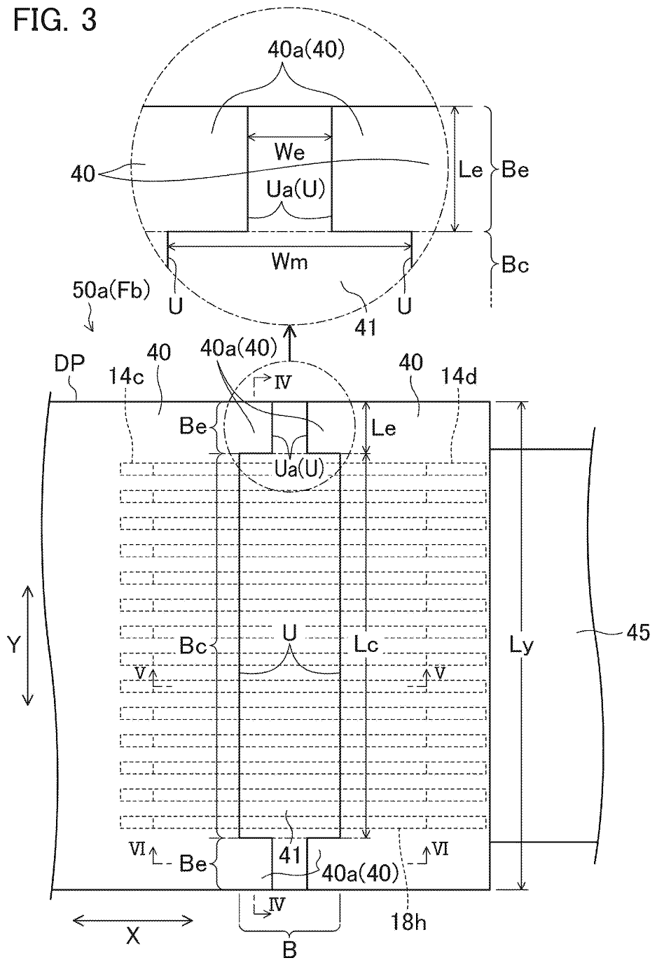

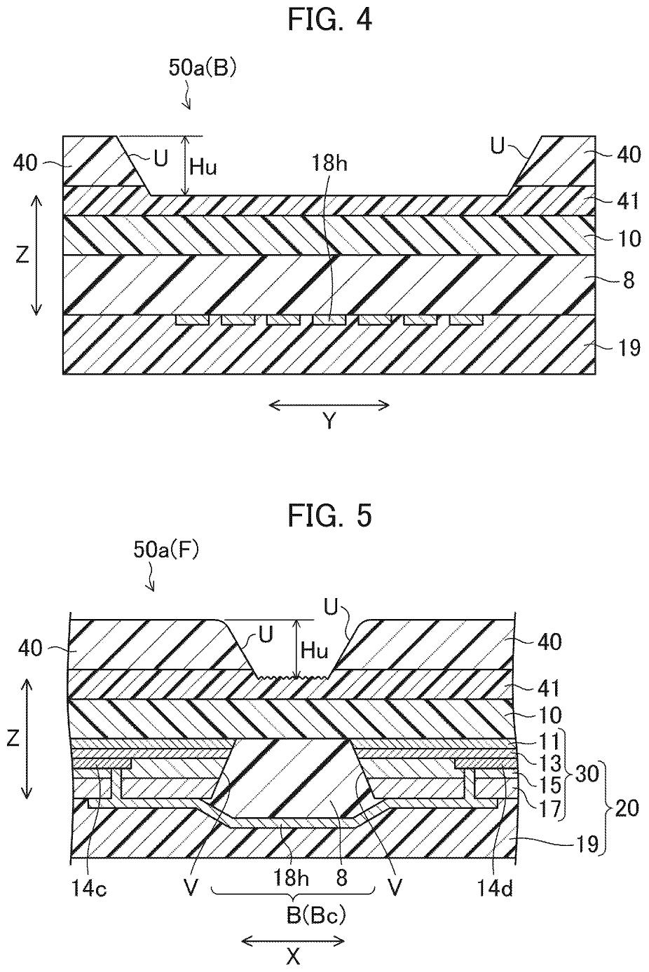

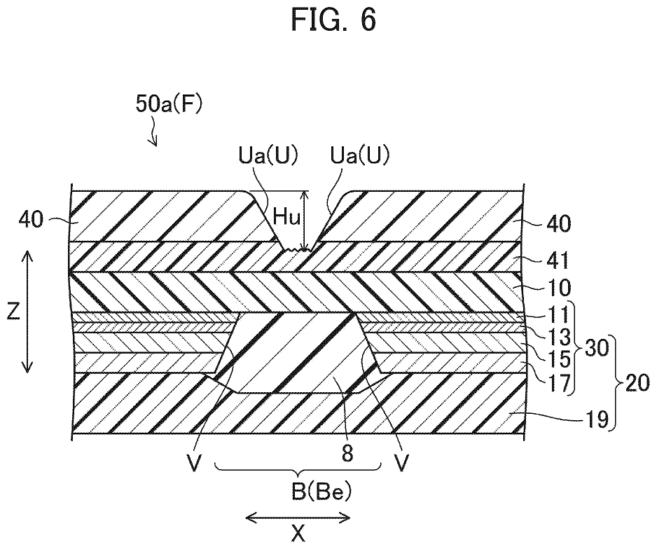

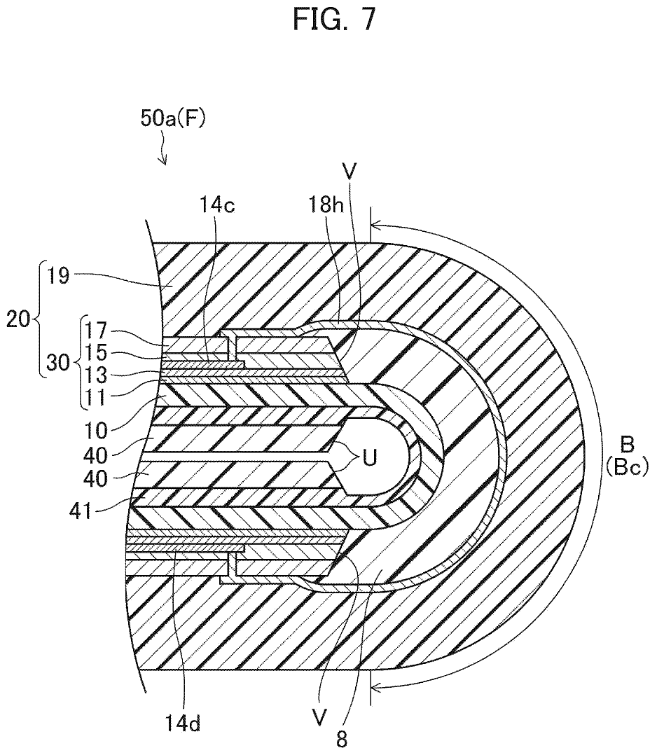

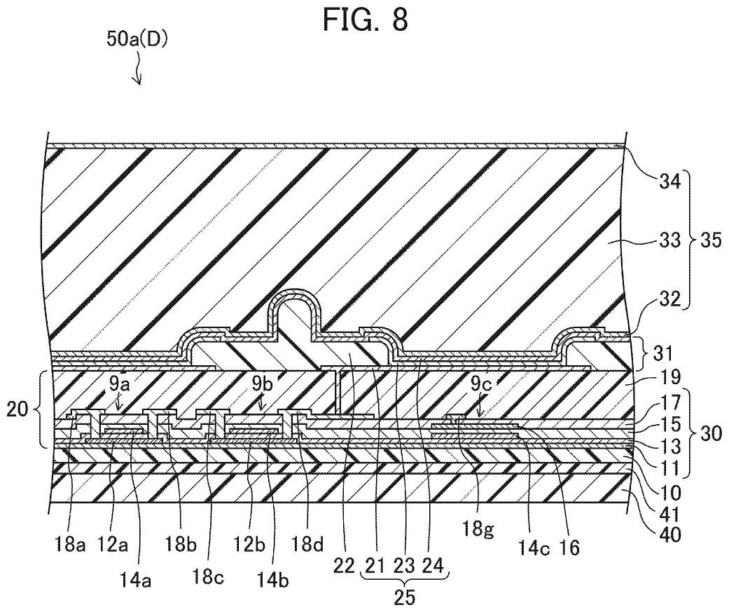

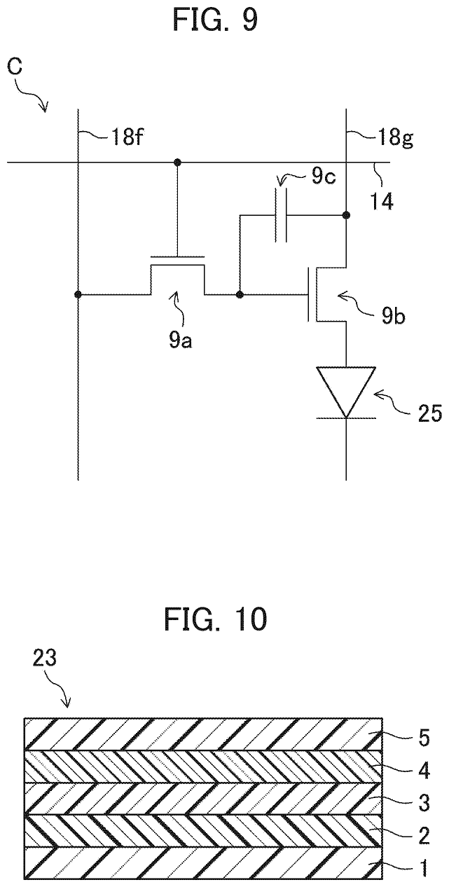

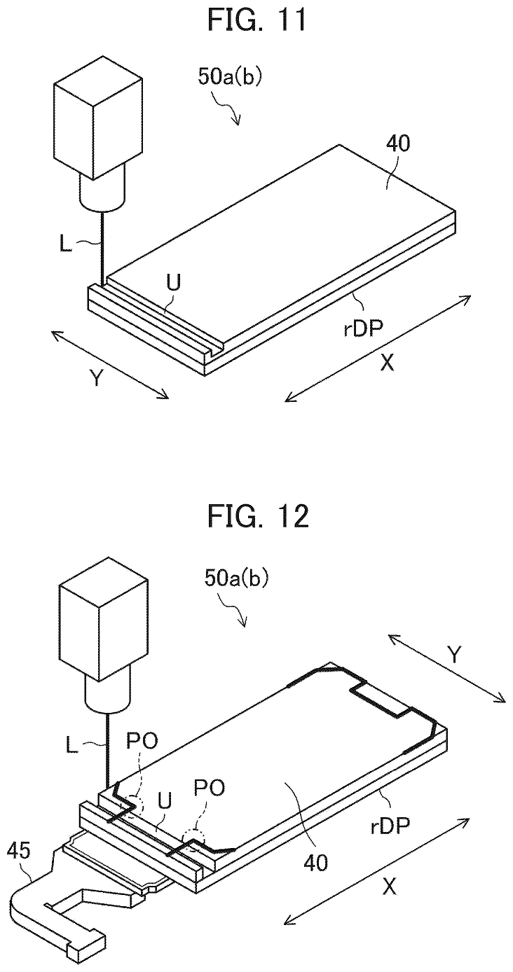

FIGS. 1 to 12 illustrate a first embodiment of a display device according to the present invention. In the embodiments below, an organic EL display device including an organic EL element is exemplified as a display device including a light-emitting element. Here, FIG. 1 is a plan view of a schematic configuration of a front face f of a display panel DP in an organic EL display device 50a according to this embodiment. FIG. 2 is a plan view of a detailed configuration of a display region D of the organic EL display device 50a. FIG. 3 is a plan view of a back face b (a face coming inwards when folded) of the display panel DP in a picture-frame region F of the organic EL display device 50a. FIG. 4 is a cross-sectional view of a folding portion B in the picture-frame region F of the organic EL display device 50a. The cross-sectional view is taken along line IV-IV in FIG. 3. FIG. 5 is a cross-sectional view of the picture-frame region F of the organic EL display device 50a. The cross-sectional view is taken along line V-V in FIG. 3. FIG. 6 is a cross-sectional view of the picture-frame region F of the organic EL display device 50a. The cross-sectional view is taken along line VI-VI in FIG. 3. FIG. 7 is a cross-sectional view of the organic EL display device 50a in a folding state. The cross-sectional view is taken along line V-V in FIG. 3. FIG. 8 is a cross-sectional view of the display region D of the organic EL display device 50a. FIG. 9 is an equivalent circuit diagram illustrating a pixel circuit C of the organic EL display device 50a. FIG. 10 is a cross-sectional view of an organic EL layer 23 included in the organic EL display device 50a. FIG. 11 is a perspective view of an example of a back-face-slit forming step in a method for manufacturing the organic EL display device 50a. FIG. 12 is a perspective view of an example of a panel outline processing step in the method for manufacturing the organic EL display device 50a.

The organic EL display device 50a illustrated in FIG. 1 includes the display panel DP. The display panel DP has, for example: the display region D shaped into a rectangle and displaying an image; the picture-frame region F shaped into a picture frame and provided around the display region D, a terminal unit T provided to one end portion (at a right end portion in FIG. 1) of the picture-frame region F in a first direction X; and the folding portion B provided in the picture-frame region F between the terminal unit T and the display region D, and extending in a second direction Y (in a vertical direction in FIG. 1) perpendicular to the first direction X. Note that this embodiment exemplifies the display region D shaped into a rectangle. Examples of the rectangle include such substantial rectangles as a rectangle having arc-like sides, a rectangle having rounded corners, and a rectangle having partially notched sides. As to the organic EL display device 50a, the first direction X (see FIGS. 1 and 3), the second direction Y (see FIGS. 1 and 3), and a third direction Z (see FIGS. 4 to 6) are defined. The first direction X is in parallel with a surface of a substrate included in the display panel DP. The second direction Y is perpendicular to the first direction X and in parallel with the surface of the substrate. The third direction Z is perpendicular to the first direction X and the second direction Y.

The display region D illustrated in FIG. 2 includes a plurality of subpixels P arranged in a matrix. Moreover, in the display region D, as illustrated in FIG. 2, for example, subpixels P having red light-emitting regions Lr for presenting red, subpixels P having green light-emitting regions Lg for presenting green, and subpixels P having blue light-emitting regions Lb for presenting blue are provided side by side. Note that, in the display region D, for example, neighboring three subpixels P each having one of a red light-emitting region Lr, a green light-emitting region Lg, and a blue light-emitting region Lb constitute one pixel. Note that the subpixels P may be arranged in any given manner such as, for example, a PenTile Matrix or a stripe.

The terminal unit T includes a plurality of terminals (not shown) arranged in the second direction Y. Furthermore, as illustrated in FIG. 1, a flexible substrate 45 such as a chip-on-film (COF) and a film-on-film (FOF) is mounted on the terminal unit T through an anisotropic conductive film (ACF). The flexible substrate 45 is electrically connected to the terminal unit T (i.e., to the plurality of terminals).

As illustrated in FIG. 1 the folding portion B is provided in parallel with the second direction Y to serve as a folding axis around which the display panel DP is foldable at an angle of 180° (in a U-shape).

Moreover, as illustrated in FIGS. 3 to 7, the organic EL display device 50a includes: a film 40 provided to the back face b of the display panel DP; and a back-face slit U (hereinafter also simply referred to as a “slit U”) provided to the film 40. As illustrated in FIG. 7, the back face b of the display panel DP is a surface of a resin substrate 10 serving as a base substrate (a base film) included in the display panel DP. The back face b is a surface (a face coming inwards when the display panel DP is folded) across from a face (a face coming outwards when the display panel DP is folded) provided with the subpixels P included in the display region D. The resin substrate 10 will be described later.

As illustrated in FIG. 3, the film 40 is provided to cover the entire back face b of the display panel DP (the entire display region D and the entire picture-frame region F). As illustrated in FIGS. 4 to 7, the film 40 is attached to the back face b of the display panel DP (the resin substrate 10) through, for example, an optical clear adhesive 41 (OCA) provided to serve as an adhesive layer. Note that the film 40 is a plastic film formed of, for example, polyethylene terephthalate (PET).

As illustrated in FIG. 3, the slit U is a slit formed in the film 40 provided to the back face b of the display panel DP. The slit U is provided toward the back face b. The slit U of the film 40 is provided to the film 40 in the folding portion B of the picture-frame region F. The slit U extends in parallel with a direction (the second direction Y) in which the folding portion B extends, and reaches opposing end portions of the picture-frame region F in the second direction Y. As illustrated in FIG. 3, the slit U is provided to: opposing end portions Be of the folding portion B in the second direction Y; and an intermediate portion (a center portion) Bc between the opposing end portions Be. That is, the slit U is provided across the entire folding portion B in the second direction and shaped into a strip shape to overlap with the folding portion B in a plan view. Hereinafter, the opposing end portions corresponding to opposing end portions of the folding portion B in the second direction Y and provided to the picture-frame region F and the slit U in the second direction Y are referred to as the “opposing end portions Be”. Likewise, the intermediate portion corresponding to an intermediate portion of the folding portion B in the second direction Y and provided to the picture-frame region F and the slit U in the second direction Y is referred to as an “intermediate portion Bc”.

Here, as illustrated in FIG. 3, in the organic EL display device 50a, the opposing end portions Be of the slit U in the second direction Y are provided with a pair of narrow width portions Ua each having a width We narrower than a width Wm in the first direction X of the intermediate portion Bc in the second direction Y. Hereinafter, a length of each of the slit U and the narrow width portions Ua in the first direction X is also simply referred to as a “width”. The narrow width portions Ua are provided to the opposing end portions Be of the folding portion B in the second direction Y. The width Wm of the slit U in the intermediate portion Bc in the second direction Y is a maximum width of the slit U. Whereas, the width We of each of the narrow width portions Ua is narrower than the maximum width Wm of the slit U (We<Wm). That is, because of the narrow width portions Ua, the width of the slit U is not entirely the same but varies at the opposing end portions Be in the second direction Y. Specifically, the width of the slit U decreases inwards in the first direction X from opposing end portions in the first direction X representing the maximum width Wm of the slit U. Hence, in the first direction X, a narrow portion (the narrow width portion Ua) is disposed in each of the opposing end portions Be of the picture-frame region F in the second direction Y, in order to reduce the width of the slit U. Thanks to the narrow portion, the width of the slit U is narrower in the opposing end portions Be of the picture-frame region F in the second direction Y than in the intermediate portion Bc between the opposing end portions Be. Thus, when the display panel DP is processed and folded, the opposing end portions Be (the narrow width portions Ua) having the narrow width portions and provided to the slit U in the second direction Y are folded more readily than the intermediate portion Bc having no narrow portion and provided to the slit U in the second direction Y (i.e., a folding angle (R) of the opposing end portions Be decreases to approximately half the folding angle of, for example, the intermediate portion Bc). As a result, alleviation is observed of tensile stress applied in the third direction Z of the display panel DP to a constriction (see PO illustrated in FIG. 12) of a rounded portion R in a base of the terminal unit T. Such a feature can reduce the risk of a crack to be caused in the vicinity of the rounded portion R in the base of the terminal unit T of the resin substrate 10 included in the display panel DP. The feature also reduces the risk of a break in a wire.

Furthermore, as illustrated in FIG. 3, a sum of lengths Le (Le+Le) of the pair of narrow width portions Ua in the second direction Y is shorter than a length Ly (Le+Lc+Le) of the picture-frame region F in the second direction Y (a total length of the picture-frame region F). Hereinafter, each of a length of the slit U, the narrow width portions Ua, and the picture-frame region F in the second direction Y is also simply referred to as a “length”. Note that the total length Ly of the picture-frame region F is equal to the maximum length (the total length) of the slit U (the opposing end portions Be and the intermediate portion Bc) including the pair of narrow width portions Ua. Whereas, the length Lc of the slit U (the intermediate portion Bc) excluding the pair of narrow width portions Ua is shorter than the total length Ly of the picture-frame region F. That is, because of the narrow width portions Ua, the length of the slit U is not entirely the same. Specifically, the length of the slit U decreases from an intermediate portion provided in the first direction X with the narrow width portions Ua toward the opposing end portions provided in the first direction X and representing the maximum width Wm of the slit U. In other words, outside the pair of narrow width portions Ua in the first direction X, the slit U does not extend to the opposing end portions Be of the picture-frame region F in the second direction Y. Hence, as illustrated in FIG. 3, the opposing end portions Be of the slit U in the second direction Y are formed into a convex shape so that the respective distal ends of the opposing end portions Be protrude in opposing directions along the second direction Y in a plan view. The convex portions are formed so that the distal ends of the convex portions face the respective opposing end portions Be of the picture-frame region F in the second direction Y. Hence, outside the pair of narrow width portions Ua in the first direction X, a remaining layer 40a of the film 40 is disposed. The remaining layer 40a of the film 40 reinforces the strength in the vicinity of the rounded portion R in the base of the terminal unit T.

Note that the maximum width Wm of the slit U may be determined in accordance with, for example, a kind of the film 40 and a pitch of an emitted laser beam to be described later. An example of the maximum width Wm is, for example, approximately 2 mm. The width We of the narrow width portions Ua in the slit U shall not be limited to a particular width as long as the width We is narrower than the width Wm. The width We is, for example, approximately 1 mm. As illustrated in FIG. 3, the length Le of the narrow width portions Ua is, for example, 1 mm or less in view of reducing stress applied to the remaining layer 40a of the film 40 in the folding portion B when the picture-frame region F is folded at the folding portion B.

Note that, as illustrated in FIGS. 4 to 7, for example, the slit U is formed to penetrate the film 40 in the thickness direction (the third direction Z). Specifically, the slit U is formed to penetrate the film 40 and expose a surface of the OCA 41. That is, as illustrated in FIGS. 3 to 7, the film 40 is removed out of the slit U.

The slit U has a depth (a length from an opening edge portion to a bottom portion (a distal end portion formed in the processing) of the slit U in the third direction Z) Hu (see FIGS. 4 to 6) as deep as the entire slit U (including the narrow width portions Ua). Note that the narrow width portions Ua have a depth different from a depth of a portion of the slit U other than the narrow width portions Ua. Specifically, the depth of the narrow width portions Ua may be either deeper or shallower than the other portion of the slit U.

As illustrated in FIG. 8 (see also FIGS. 4 to 7), the organic EL display device 50a includes: the resin substrate 10 provided to serve as a base substrate; and a thin-film transistor (hereinafter also referred to as “TFT”) layer 20 having an inorganic multilayer film 30 provided on the resin substrate 10 to serve as at least one inorganic insulating film. The resin substrate 10 and the TFT layer 20 are a configuration of the display panel DP toward the front face f.

The resin substrate 10 is made of, for example, such a material as polyimide resin.

The TFT layer 20 illustrated in FIG. 8 (see also FIGS. 5 to 7) includes: a base coat film 11 provided on the resin substrate layer 10; a plurality of first TFTs 9a, a plurality of second TFTs 9b, and a plurality of capacitors 9c, each of which is provided on the base coat film 11 for a corresponding one of the subpixels P; and a second planarization film 19 provided above the first TFTs 9a, the second TFTs 9b, and the capacitors 9c. Note that, as will be described later, a first planarization film 8 (see FIGS. 5 to 7) is provided to the folding portion B of the picture-frame region F. Here, the TFT layer 20 illustrated in FIG. 8 includes: the base coat film 11; semiconductor layers 12a and 12b; a gate insulating film 13; a gate line 14 (see FIG. 2); gate electrodes 14a and 14b; a first wiring layer such as a lower conductive layer 14c; a first interlayer insulating film 15; a second wiring layer such as an upper conductive layer 16; a second interlayer insulating film 17; a third wiring layer such as a source line 18f (see FIG. 2), source electrodes 18a and 18c, drain electrodes 18b and 18d, and a power supply line 18g; and the second planarization film 19, all of which are sequentially stacked on top of another above the resin substrate 10. Furthermore, as illustrated in FIGS. 2 and 9, the TFT layer 20 includes a plurality of the gate lines 14 extending in parallel with one another in the horizontal direction in the drawings. Moreover, as illustrated in FIGS. 2 and 9, the TFT layer 20 includes a plurality of the source lines 18f extending in a direction intersecting with (perpendicular to) the plurality of gate lines 14; that is, extending in parallel with one another in the vertical direction in the drawings. In addition, as illustrated in FIGS. 2 and 9, the TFT layer 20 includes a plurality of the power supply lines 18g extending in parallel with one another in the vertical direction in the drawings. Note that, as illustrated in FIG. 2, the power supply lines 18g and the source lines 18f are provided side by side. Moreover, in the TFT layer 20, as illustrated in FIG. 9, each subpixel P includes: a first TFT 9a; a second TFT 9b; and a capacitor 9c, all of which constitute the pixel circuit C. A plurality of the pixel circuits C, each corresponding to one of the subpixels P, is arranged in a matrix.

Each of the base coat film 11, the gate insulating film 13, the first interlayer insulating film 15, and the second interlayer insulating film 17 is an inorganic monolayer insulating film made of such a substance as, for example, silicon nitride (SiNₓ: x is a positive number), silicon oxide (SiO₂), or silicon oxynitride (SiON). Alternatively, each film is an inorganic multilayer insulating film made of these substances. Each of the semiconductor layers 12a and 12b is, for example, a low-temperature-polysilicon film or an In—Ga—Zn—O-based oxide semiconductor film. Each of the first wiring layer, the second wiring layer, and the third wiring layer is, for example, either a metal monolayer film made of such a metal as molybdenum (Mo), titanium (Ti), aluminum (Al), copper (Cu), or tungsten (W), or a metal multilayer film made of such metals as Mo (an upper layer)/Al (a middle layer)/Mo (a lower layer), Ti/Al/Ti, Al (an upper layer)/Ti (a lower layer), Cu/Mo, or Cu/Ti. Note that the third wiring layer is preferably formed of a metal multilayer film such as Ti/Al/Ti.

The first TFT 9a and the second TFT 9b are p-type TFTs including the semiconductor layers 12a and 12b doped with impurities such as boron. The semiconductor layers 12a and 12b will be described later.

As illustrated in FIG. 9, in each subpixel P, the first TFT 9a is electrically connected to the corresponding gate line 14 and source line 18f. Furthermore, as illustrated in FIG. 8, the first TFT 9a includes: the semiconductor layer 12a; the gate insulating film 13; a gate electrode 14a; the first interlayer insulating film 15; the second interlayer insulating film 17; and the source electrode 18a and the drain electrode 18b, all of which are sequentially provided above the base coat film 11. Here, as illustrated in FIG. 8, the semiconductor layer 12a is shaped into an island shape and provided on the base coat film 11. For example, the semiconductor layer 12a includes a channel region, a source region, and a drain region. Moreover, as illustrated in FIG. 8, the gate insulating film 13 is provided to cover the semiconductor layer 12a. Furthermore, as illustrated in FIG. 8, the gate electrode 14a is provided on the gate insulating film 13 to overlap with the channel region of the semiconductor layer 12a. In addition, as illustrated in FIG. 8, the first interlayer insulating film 15 and the second interlayer insulating film 17 are sequentially provided to cover the gate electrode 14a. Moreover, as illustrated in FIG. 8, the source electrode 18a and the drain electrode 18b are spaced apart from each other on the second interlayer insulating film 17. Furthermore, as illustrated in FIG. 8, the source electrode 18a and the drain electrode 18b are respectively and electrically connected to the source region and the drain region of the semiconductor layer 12a through respective contact holes formed in the multilayer film including the gate insulating film 13, the first interlayer insulating film 15, and the second interlayer insulating film 17.

As illustrated in FIG. 9, in each subpixel P, the second TFT 9b is electrically connected to the corresponding first TFT 9a and power supply line 18g. Furthermore, as illustrated in FIG. 8, the second TFT 9b includes: the semiconductor layer 12b; the gate insulating film 13; a gate electrode 14b; the first interlayer insulating film 15; the second interlayer insulating film 17; and the source electrode 18c and the drain electrode 18d, all of which are sequentially provided above the base coat film 11. Here, as illustrated in FIG. 8, the semiconductor layer 12b is shaped into an island shape and provided on the base coat film 11. For example, the semiconductor layer 12b includes a channel region, a source region, and a drain region. Moreover, as illustrated in FIG. 8, the gate insulating film 13 is provided to cover the semiconductor layer 12b. Furthermore, as illustrated in FIG. 8, the gate electrode 14b is provided on the gate insulating film 13 to overlap with the channel region of the semiconductor layer 12b. In addition, as illustrated in FIG. 8, the first interlayer insulating film 15 and the second interlayer insulating film 17 are sequentially provided to cover the gate electrode 14b. Moreover, as illustrated in FIG. 8, the source electrode 18c and the drain electrode 18d are spaced apart from each other on the second interlayer insulating film 17. Furthermore, as illustrated in FIG. 8, the source electrode 18c and the drain electrode 18d are respectively and electrically connected to the source region and the drain region of the semiconductor layer 12b through respective contact holes formed in the multilayer film including the gate insulating film 13, the first interlayer insulating film 15, and the second interlayer insulating film 17.

Note that, in this embodiment, the first TFTs 9a and the second TFTs 9b are, for example, top gate TFTs. Alternatively, the first TFTs 9a and the second TFTs 9b may be bottom gate TFTs.

As illustrated in FIG. 9, in each subpixel P, the capacitor 9c is electrically connected to the corresponding first TFT 9a and power supply line 18g. Here, as illustrated in FIG. 8, the capacitor 9c includes: the lower conductive layer 14c formed of the same material as, and in the same layer as, the second gate electrodes 14a and 14b; the first interlayer insulating film 15 provided to cover the lower conductive layer 14c; and the upper conductive layer 16 provided on the first interlayer insulating film 15 to overlap with the lower conductive layer 14c. Note that the upper conductive layer 16 in FIG. 8 is electrically connected to the power supply line 18g through a contact hole formed in the second interlayer insulating film 17.

The second planarization film 19 has a flat surface in the display region D. The second planarization film 19 is made of such a material as, for example, an organic resin material such as polyimide resin or acrylic resin, or a polysiloxane-based spin-on-glass (SOG) material.

The inorganic multilayer film 30 is at least one inorganic insulating film included in the TFT layer 20. As illustrated in FIGS. 5 to 8, the inorganic multilayer film 30 includes four inorganic insulating films: the base coat film 11 (a first inorganic insulating film) serving as a moisture-proof film; the gate insulating film 13 (a second inorganic insulating film); the first interlayer insulating film 15 (a third inorganic insulating film); and the second interlayer insulating film 17 (a fourth inorganic insulating film), all of which are stacked on top of another above the resin substrate 10.

Furthermore, as illustrated in FIGS. 5 to 7, the organic EL display device 50a includes: the resin substrate 10; the inorganic multilayer film 30; a front-face slit V (hereinafter also simply referred to as a “slit V”) provided in the inorganic multilayer film 30 to extend in the second direction Y; the first planarization film 8 covering the slit V; a connection wire 18h; and the second planarization film 19, all of which are provided to the folding portion B in the picture-frame region F to serve as a configuration of the display panel DP toward the front face f.

The slit V is a slit formed in the inorganic multilayer film 30 disposed on the front face f of the display panel DP. The slit V is provided toward the front face f of the panel. As illustrated in FIGS. 5 to 7, the slit V is provided to the folding portion B in the picture-frame region F in order to penetrate the inorganic multilayer film 30 and expose the surface (the lower surface in FIGS. 5 and 6) of the resin substrate 10. The slit V of the inorganic multilayer film 30 is formed in a shape of a groove penetrating in parallel with a direction in which the folding portion B extends (in the second direction Y). Furthermore, the slit V extends to the opposing ends of the picture-frame region F in the second direction Y, and is shaped into a strip shape in a plan view. The slit V of the inorganic multilayer film 30 reduces stress applied to the inorganic multilayer film 30 when the picture-frame region F is folded at the folding portion B. As a result, the slit V reduces the risks of damage to the inorganic multilayer film 30 when the picture-frame region F is folded, and of a break in the connection wire 18h provided on the inorganic multilayer film 30.

Furthermore, the front face slit V overlaps with the back face slit U in a plan view. Hence, when the picture-frame region F is folded at the folding portion B, the stress to the film 40 can be reduced in the folding portion B. Such a feature further reduces the risks of damage to the inorganic multilayer film 30 and of a break in the connection wire 18h in folding the picture-frame region F.

Note that, as illustrated in FIGS. 5 to 7, for example, the slit V is formed to penetrate the inorganic multilayer film 30 in the thickness direction (the third direction Z).

As illustrated in FIGS. 4 to 7, the first planarization film 8 is shaped into a strip shape in a plan view and provided to fill the slit V. The first planarization film 8 is formed of, for example, the same material as that of the second planarization film 19.

As illustrated in FIGS. 5 and 7 (see also FIGS. 3 and 4), a plurality of the connection wires 18h is provided to opposing edge portions of the second interlayer insulating film 17 and on the first planarization film 8, which are provided with the slit V. Furthermore, as illustrated in FIGS. 5 and 7, the connection wires 18h extend in parallel with one another in the first direction X and intersect with the slit V. Note that as illustrated in FIG. 3, the connection wires 18h are arranged in the intermediate portion Bc included in the folding portion B; whereas, the connection wires 18h are not arranged in the opposing end portions Be included in the folding portion B and provided with the narrow width portions Ua. Here, the connection wires 18h are formed of the same material as, and in the same layer as, for example, the source electrodes 18a. Furthermore, as illustrated in FIGS. 5 and 7 (see also FIG. 3), end portions of the connection wires 18h toward the display region D are electrically connected to a first gate conductive layer 14c through contact holes formed in a multilayer film including the first interlayer insulating film 15 and the second interlayer insulating film 17. Note that the first gate conductive layer 14c is provided between the gate insulating film 13 and the first interlayer insulating film 15, and electrically connected to signal wires (such as the gate lines 14, the source lines 18f, and the power supply lines 18g) of the TFT layer 20 in the display region D. Furthermore, as illustrated in FIGS. 5 and 7, end portions of the connection wires 18h toward the terminal unit T are electrically connected to a second gate conductive layer 14d through contact holes formed in the multilayer film including the first interlayer insulating film 15 and the second interlayer insulating film 17. Note that the second gate conductive layer 14d is provided between the gate insulating film 13 and the first interlayer insulating film 15, and extends to the terminal unit T. Then, the second gate conductive layer 14d is electrically connected to each of the terminals in the terminal unit T. As can be seen, through the connection wires 18h, each of the signal wires of the TFT layer 20 in the display region D is electrically connected to a corresponding one of the terminals in the terminal unit T.

As illustrated in FIGS. 4 to 8, the second planarization film 19 is provided to cover the connection wires 18h, the second interlayer insulating film 17, and the first planarization film 8.

Furthermore, as illustrated in FIG. 8, the organic EL display device 50a includes: an organic-EL-element layer 31 provided to serve as a light-emitting-element layer included in the display region D; and a sealing film 35 provided on the organic-EL-element layer 31. The organic-EL-element layer 31 and the sealing film 35 are provided in the display region D to serve as a configuration of the display panel DP toward the front face f.

As illustrated in FIG. 8, the organic-EL-element layer 31 includes a plurality of organic EL elements 25. The organic EL elements 25, serving as a plurality of light-emitting elements, are arranged in a matrix so as to correspond to the plurality of respective subpixels P.

As illustrated in FIG. 8, the organic EL elements 25 include: a plurality of first electrodes 21 sequentially provided on the second planarization film 19; a plurality of the organic EL layers 23 provided on the first electrode 21 for a corresponding one of the subpixels P; and a second electrode 24 provided on the organic EL layer 23 in common to the plurality of subpixels P. Furthermore, as illustrated in FIG. 8, the organic EL elements 25 are covered with the sealing film 35.

The first electrodes 21 illustrated in FIG. 8 are arranged on the second planarization film 19 in a matrix so that each of the first electrodes 21 is provided for a corresponding one of the plurality of subpixels P. Furthermore, each of the first electrodes 21 illustrated in FIG. 8 is electrically connected to the drain electrode 18d (or the source electrode 18c) of the second TFT 9b through a contact hole formed in the second planarization film 19. Moreover, the first electrode 21 has a function of injecting holes into the organic EL layer 23. In addition, the first electrode 21 is formed of a material preferably having a large work function to improve efficiency in injecting the holes into the organic EL layer 23. Here, examples of the material forming the first electrode 21 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). In addition, the first electrode 21 may be made of, for example, an alloy of astatine (At)/astatine oxide (AtO₂). Furthermore, the first electrode 21 may be made of a conductive oxide such as, for example, tin oxide (SnO), zinc oxide (ZnO), indium tin oxide (ITO), or indium zinc oxide (IZO). In addition, the first electrode 21 may be formed of a plurality of layers made of the above materials and stacked on top of another. Note that examples of compound materials having a large work function include indium tin oxide (ITO) and indium zinc oxide (IZO).

The first electrode 21 has a peripheral end portion covered with an edge cover 22 provided in a grid pattern in common to the plurality of subpixels P. Here, exemplary materials of the edge cover 22 include either positive photosensitive resin materials such as polyimide resin, acrylic resin, polysiloxane resin, and novolak resin, or a polysiloxane-based SOG material. As illustrated in FIG. 8, the edge cover 22 has a surface partially protruding upwards in the drawing to serve as a pixel photo spacer shaped into an island shape.

As illustrated in FIG. 8, the organic EL layers 23 are arranged on the respective first electrodes 21 and provided in a matrix to correspond to the plurality of respective subpixels P. Here, as illustrated in FIG. 10, each of the organic EL layers 23 includes: a hole injection layer 1; a hole transport layer 2; a light-emitting layer 3, an electron transport layer 4, and an electron injection layer 5, all of which are sequentially provided above the first electrode 21.

The hole injection layer 1 is also referred to as an anode buffer layer. The hole injection layer 1 has a function of approximating energy levels between the first electrode 21 and the organic EL layer 23 to improve efficiency in injecting the holes from the first electrode 21 into the organic EL layer 23. Here, examples of a material forming the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has a function of improving efficiency in transporting the holes from the first electrode 21 to the organic EL layer 23. Here, examples of a material forming the hole transport layer 2 include a porphyrin derivative, an aromatic tertiary amine compound, a styrylamine derivative, polyvinyl carbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, zinc selenide, and zinc selenide.

The light-emitting layer 3 is a region where the holes and the electrons are injected respectively from the first electrode 21 and the second electrode 24, and recombine together, when a voltage is applied with the first electrode 21 and the second electrode 24. Here, the light-emitting layer 3 is formed of a material having high light emission efficiency. Examples of the material forming the light-emitting layer 3 include a metal oxinoid compound [8-hydroxyquinoline metal complex], a naphthalene derivative, an anthracene derivative, a diphenylethylene derivative, a vinylacetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzthiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rhodamine derivative, an aquizine derivative, phenoxazone, a quinacridone derivative, rubrene, poly-p-phenylenevinylene, and polysilane.

The electron transport layer 4 has a function of efficiently moving the electrons to the light-emitting layer 3. Here, examples of a material forming the electron transport layer 4 include, as organic compounds, an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has a function of approximating energy levels between the second electrode 24 and the organic EL layer 23 to improve efficiency in injecting the electrons from the second electrode 24 into the organic EL layer 23. Such a function can decrease a drive voltage of the organic EL element 25. Note that the electron injection layer 5 is also referred to as a cathode buffer layer. Here, examples of a material forming the electron injection layer 5 include: inorganic alkali compounds such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 8, the second electrode 24 is provided to cover each organic EL layer 23 and the edge cover 22. Moreover, the second electrode 24 has a function of injecting the electrons into the organic EL layer 23. Furthermore, the second electrode 24 is formed of a material preferably having a small work function to improve efficiency in injecting the electrons into the organic EL layer 23. Here, examples of the material forming the second electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru,) manganese (Mn), indium (In), magnesium (Mg), lithium (Li), ytterbium (Yb), and lithium fluoride (LiF). Moreover, the second electrode 24 may be formed of an alloy such as, for example, magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), or lithium fluoride (LiF)/calcium (Ca)/aluminum (Al). Furthermore, the second electrode 24 may be formed of a conductive oxide such as tin oxide (SnO), zinc oxide (ZnO), indium tin oxide (ITO), or indium zinc oxide (IZO). In addition, the second electrode 24 may be formed of a plurality of layers made of the above materials and stacked on top of another. Note that examples of the material having a small work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As illustrated in FIG. 8, the sealing film 35 includes: a first inorganic sealing insulating film 32 provided to cover the second electrode 24; an organic sealing film 33 provided on the first inorganic sealing insulating film 32; and a second inorganic sealing insulating film 34 provided to cover the organic sealing film 33. The sealing film 35 has a function of protecting the organic EL layer 23 from such substances as water and oxygen. Here, the first inorganic sealing insulating film 32 and the second inorganic sealing insulating film 34 are made of, for example, inorganic materials such as silicon oxide (SiO₂), aluminum oxide (Al₂O₃), a silicon nitride (SiNx: x is a positive number) such as trisilicon tetranitride (Si₃N₄), and silicon carbonitride (SiCN). Moreover, the organic sealing film 33 is formed of such an organic material as, for example, acrylic resin, polyurea resin, parylene resin, polyimide resin, or polyamide resin.

The above organic EL display device 50a displays an image as follows: In each of the subpixels P, a gate signal is input to the first TFT 9a through the gate line 14 to turn ON the first TFT 9a. Through the source line 18f, a data signal is written to the gate electrode 14b of the second TFT 9b and the capacitor 9c. A current based on a gate voltage of the second TFT 9b is supplied from the power supply line 18g to the organic EL layer 23, and the light-emitting layer 3 of the organic EL layer 23 emits light to display an image. Note that, in the organic EL display device 50a, even if the first TFT 9a turns OFF, the gate voltage of the second TFT 9b is held in the capacitor 9c. Hence, the light-emitting layer 3 keeps emitting light until a gate signal in the next frame is input.

Described next will be a method for manufacturing the organic EL display device 50a of this embodiment. The method for manufacturing the organic EL display device 50a of this embodiment includes: a film attaching step; and a back-face-slit forming step. Furthermore, the method for manufacturing the organic EL display device 50a includes, as steps of forming the display panel DP: a resin-substrate forming step; a TFT-layer forming step; an organic-EL-element-layer forming step; and a sealing-film forming step.

### Resin-Substrate Forming Step

For example, a support substrate (not shown) such as a glass substrate is coated with non-photosensitive polyimide resin. After that, the coating film is pre-baked and post-baked to form the resin substrate 10.

### TFT-Layer Forming Step

The base coat film 11, the first TFT 9a, the second TFT 9b, the capacitor 9c, and the second planarization film 19 are formed by a known technique on the resin substrate 10 formed at the resin-substrate forming step. Hence, the TFT layer 20 is formed. Here, when the first TFT 9a and the second TFT 9b are formed, prior to the formation of, for example, the source electrode 18a, first, the inorganic multilayer film 30 is dry-etched in the folding portion B of the picture-frame region F so that the slit V is formed toward the front face of the panel. Next, the first planarization film 8 is formed to fill the slit V. After that, the connection wires 18h are formed together with, for example, the source electrodes 18a. Finally, furthermore, the second planarization film 19 is formed of the same material as that of the first planarization film 8, in order to cover the connection wires 18h.

### Organic-EL-Element-Layer Forming Step

On the second planarization film 19 of the TFT layer 20 (specifically, the second planarization film 19 in the display region D) formed at the TFT-layer forming step, the first electrode 21, the edge cover 22, the organic EL layer 23 (including the hole injection layer 1, the hole transport layer 2, the light-emitting layer 3, the electron transport layer 4, and the electron injection layer 5), and the second electrode 24 are formed using a known technique so that the organic EL element 25 is formed. Hence, the organic-EL-element layer 31 is formed.

### Sealing-Film Forming Step

First, on the substrate surface provided with the organic-EL-element layer 31 formed at the organic-EL-element-layer forming step, an inorganic insulating film such as, for example, a silicon nitride film, a silicon oxide film, or a silicon oxynitride film is deposited to cover each of the organic EL elements 25 by the plasma CVD using a CMM as a vapor deposition mask. Hence, the first inorganic sealing insulating film 32 is formed. Then, on the first inorganic sealing insulating film 32, an organic resin material such as acrylic resin is deposited by, for example, inkjet printing. Hence, the organic sealing film 33 is formed. After that, an inorganic insulating film such as, for example, a silicon nitride film, a silicon oxide film, or a silicon oxynitride film is deposited to cover the organic sealing film 33 by the plasma CVD using a CMM as a vapor deposition mask, so as to form the second inorganic sealing insulating film 34. Hence, the sealing film 35 is formed. Through the above steps, the sealing film 35 can be formed in the display region D to include the first inorganic sealing insulating film 32, the organic sealing film 33, and the second inorganic sealing insulating film 34 sequentially stacked on top of another.

### Film Attaching Step

After the resin-substrate forming step, the resin substrate 10 is irradiated with a laser beam from toward the support substrate. Hence, the support substrate is removed from a surface, of the resin substrate 10, across from a face provided with the TFT layer 20 (a face provided with the subpixels P included in the display region D). Next, when the support substrate is removed from the surface of the resin substrate 10, the film 40 is attached to the surface through the OCA 41.

### Back-Face-Slit Forming Step

As illustrated in FIG. 11, for example, a CO₂ laser beam L is emitted to a portion included in the film 40 attached at the film attaching step and overlapping with the folding portion B in a plan view. The CO₂ laser beam L is emitted twice or more in parallel with the direction in which the folding portion B extends (the second direction Y). Hence, the slit U is formed. A pitch of the laser beam L to be emitted shall not be limited to a particular pitch. For example, the pitch is, for example, approximately 0.1 mm.

The slit U is formed, for example, as follows. The laser beam L having a predetermined emission intensity is emitted in the second direction Y to the film 40 disposed in the folding portion B, so that the film 40 undergoes laser-slitting processing. Hence, a slit is formed linearly in a plan view. Next, the laser-slitting processing is carried out twice or more at a predetermined pitch in the first direction X. Hence, almost all the film 40 is removed from the folding portion B, so that the slit U can be formed into a strip shape in a plan view. Here, when the laser beam L is emitted in the second direction Y, the emission distance or the emission time is changed so that the width We of the slit U at the opposing end portions Be in the second direction Y is narrower than the maximum width Wm of the intermediate portion Bc in the second direction Y. Specifically, in relation to the emission distance or the emission time (a reference distance or a reference time) for an intermediate portion of the slit U in the first direction X when the laser-slitting processing is given up to the opposing end portions Be of the picture-frame region F in the second direction Y, the laser beam L may be emitted in a shorter distance or for a shorter time for opposing end portions representing the maximum width Wm of the slit U in the first direction X. In other words, the slit U for the intermediate portion in the first direction X is formed to extend to the opposing end portions Be of the picture-frame region F in the second direction Y; whereas, the slit U for the opposing end portions representing the maximum width Wm of the slit U in the first direction X is not formed up to the opposing end portions Be of the picture-frame region F in the second direction Y. Through the above steps, the opposing end portions Be of the slit U in the second direction Y are provided with a pair of the narrow width portions Ua.

Note that, in forming the slit U, the laser beam L is emitted at an intensity at which the film 40 is removed and the surface of the OCA 41 is exposed but the OCA 41 is not penetrated. As illustrated in FIGS. 4 to 6, a side face (a processed end face) of the slit U formed as described above is tapered in a cross-sectional view because of the thermal effect of the laser beam L. As illustrated in FIGS. 5 and 6, the slit U has a bottom portion (an exposed portion of the surface of the OCA 41) shaped into a flat face with minute asperities in a cross-sectional view. Here, the asperities are edges of a plurality of processing lines overlapping with one another.

Furthermore, the method for manufacturing the organic EL display device 50a may include a panel outline processing step following the back-face-slit forming step.

### Panel Outline Processing Step

As illustrated in FIG. 12, the display panel DP has the slit U on the back face of the panel while an outline of the display panel DP is not processed. The display panel DP undergoes laser-cut processing in which the laser beam L is emitted to the display panel DP to cut the outline of the panel (at least a portion of the panel outline) into a predetermined shape (e.g., cut into a rounded shape in the vicinity of the terminal unit T). Thanks to the laser-cut processing, the display panel DP has a processed outline (a cut outline).

As can be seen, the organic EL display device 50a is successfully manufactured.

### Advantageous Effects

As described above, the organic EL display device 50a according to this embodiment can achieve the advantageous effects below.

(1) As to the organic EL display device 50a, the film 40 provided to the back face b of the display panel DP has the slit U extending to the opposing end portions Be of the picture-frame region F in the second direction Y and provided toward the back face of the panel so that the slit U overlaps with the folding portion B of the picture-frame region F in a in a plan view. The opposing end portions Be of the slit U in the second direction Y are provided with the pair of narrow width portions Ua each having a width We narrower than the width Wm of the intermediate portion Bc in the second direction Y (We<Wm). That is, in order to reduce the width Wm of the slit U, a narrow portion (a convex portion in a plan view) is disposed to each of the opposing end portions Be of the picture-frame region F in the second direction Y. Thus, when the display panel DP is processed and folded, the opposing end portions Be having the narrow width portions and provided to the slit U in the second direction Y are folded more readily than the intermediate portion Bc having no narrow portion and provided to the slit U in the second direction Y (i.e., a folding angle (R) of the opposing end portions Be decreases to approximately half the folding angle of, for example, the intermediate portion Bc). As a result, alleviation is observed of tensile stress applied in the third direction Z of the display panel DP to a constriction (see PO illustrated in FIG. 12) of a rounded portion R in a base of the terminal unit T. Such a feature can reduce the risk of a crack to be caused in the vicinity of the rounded portion R in the base of the terminal unit T of the resin substrate 10 in the rounded portion. The feature can also reduce the risk of a break in a wire (e.g., a connection wire 18h).

(2) Furthermore, as to the organic EL display device 50a, the remaining layer 40a of the film 40 is left outside the pair of narrow width portions Ua in the first direction X. The remaining layer 40a reinforces the strength in the vicinity of the rounded portion R in the base of the terminal unit T. Such a feature makes it possible to provide resistance to the stress, and further reduce the risks of a crack in the resin substrate 10 and a break in a wire.

### Second Embodiment

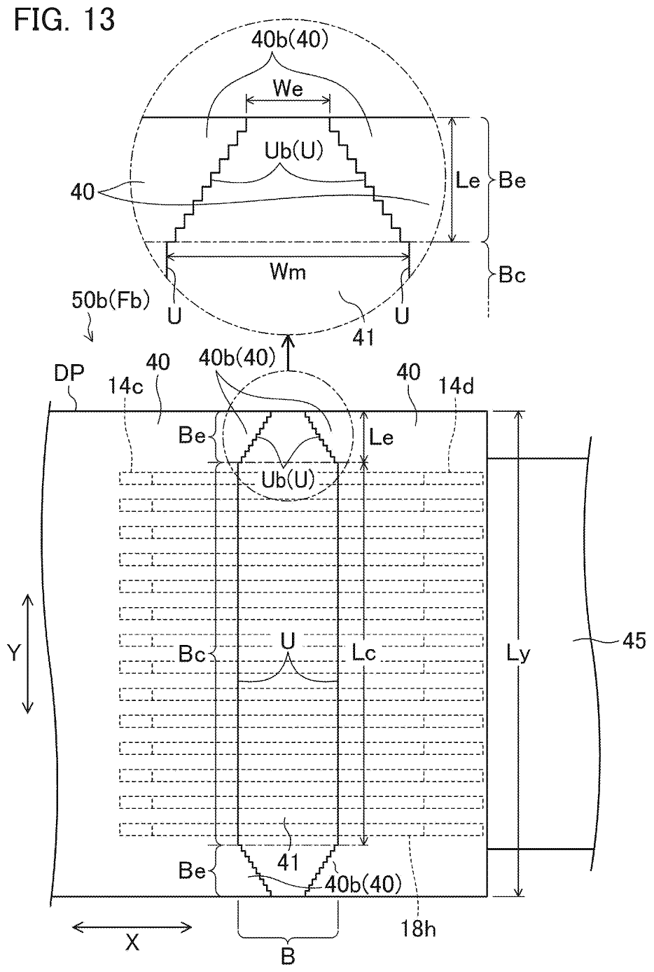

Next, a second embodiment of the present invention will be described with reference to FIG. 13. FIG. 13 is a plan view of the back face b (a face coming inwards when folded) of the display panel in the picture-frame region F of an organic EL display device 50b according to this embodiment. FIG. 13 corresponds to FIG. 3. Note that the overall configuration of the organic EL display device 50b including the display region D and the picture-frame region F is the same as that of the organic EL display device 50a in the first embodiment except for the configuration of the folding portion B, and a detailed description thereof will be omitted. Furthermore, like reference signs designate identical constituent features between this embodiment and the first embodiment. Such constituent features will not be elaborated upon.

The organic EL display device 50b is different from the organic EL display device 50a in that a shape of the opposing end portions Be of the slit U in the second direction Y; that is, a shape of a pair of narrow width portions Ub, is different from a shape of the pair of narrow width portions Ua. Specifically, as illustrated in FIG. 13, the opposing end portions Be of the slit U in the second direction Y are tapered so that the respective distal ends of the opposing end portions Be protrude in opposing directions along the second direction Y in a plan view. Each of the narrow width portions Ub has a tapered portion shaped into a tapered shape and formed, for example, stepwise in a plan view. As illustrated in FIG. 13, a remaining layer 40b of the film 40 is disposed outside the pair of narrow width portions Ub in the first direction X.

As illustrated in FIG. 13, the pair of narrow width portions Ub gradually reduces the width of the slit U from the intermediate portion Bc in the second direction Y toward the opposing end portions Be in the second direction Y. The width (the smallest width) We of the narrow width portions Ub in the slit U shall not be limited to a particular width as long as the width We is narrower than the maximum width Wm of the slit U. The width We of the narrow width portions Ub may be as wide as the width We of the narrow width portions Ua (e.g., approximately 1 mm). Furthermore, the length of the slit U gradually decreases from an intermediate portion in the first direction X toward opposing end portions in the first direction X representing the maximum width Wm of the slit U. A length Le of the narrow width portions Ub may be equal to the length Le of the narrow width portions Ua (e.g., 1 mm or less).

As to the organic EL display device 50a, at boundaries between the intermediate portion Bc and the opposing end portions Be of the folding portion B in the second direction Y, the maximum width Wm of the slit U drastically changes (narrows) to the width We of the narrow width portions Ua. Whereas, as to the organic EL display device 50b of this embodiment, the maximum width Wm of the slit U gently changes to the width We of the narrow width portions Ub by, for example, every pitch at which a laser beam is emitted (e.g., 0.1 mm).

The organic EL display device 50b can be manufactured, changing a condition to emit a laser beam when the narrow width portions Ub are formed for the organic EL display device 50a at the back-face-slit forming step. Specifically, in relation to an emission distance or an emission time (a reference distance or a reference time) for an intermediate portion of the slit U in the first direction X when the laser-slitting processing is given up to the opposing end portions Be of the picture-frame region F in the second direction Y, the laser beam L may be emitted gradually in a shorter distance or for a shorter time (e.g., by every pitch at which a laser beam is emitted) from the intermediate portion of the slit U in the first direction X toward opposing end portions representing the maximum width Wm of the slit U in the first direction X. Through the above steps, the opposing end portions Be of the slit U in the second direction Y are provided with a pair of the narrow width portions Ub.

### Advantageous Effects

As described above, the organic EL display device 50b according to this embodiment can achieve the advantageous effects below in addition to the above advantageous effects (1) and (2).

(3) As to the organic EL display device 50b, the tapered narrow width portions Ub are formed in a portion included in the film 40 and overlapping in a plan view with the opposing end portions Be of the folding portion B in the second direction Y. The tapered narrow width portions Ub provide a gently narrow portion to each of the opposing end portions Be of the picture-frame region F in the second direction Y, in order to gradually reduce the width of the slit U. As a result, a folding curvature of the display panel DP is gentle in the folding processing, thereby reinforcing strength in the vicinity of the boundaries between the intermediate portion Bc and the opposing end portions Be of the folding portion B in the second direction Y. Such a feature makes it possible to reduce the risks of a crack in the resin substrate 10 and a break in a wire in the vicinity of the boundaries.

### Other Embodiments

In each of the above embodiments, the inorganic multilayer film includes four layers of the base coat film, the gate insulating film, the first interlayer insulating film, and the second interlayer insulating film all of which are sequentially stacked on top of another. Alternatively, the inorganic multilayer film may be made of either one layer of the base coat film or two layers of the base coat film and the gate insulating film.

In each of the above embodiments, the exemplified organic EL layer has a multilayer structure including five layers such as a hole injection layer, a hole transport layer, a light-emitting layer, an electron transport layer, and an electron injection layer. Alternatively, the organic EL layer may have a multilayer structure including three layers such as, for example, a hole-injection-and-hole-transport layer, a light-emitting layer, and an electron-transport-and-electron-injection layer.

Moreover, in each of the above embodiments, the exemplified organic EL display device includes a first electrode as an anode and a second electrode as a cathode. The present invention can also be applied to an organic EL display device whose multilayer structure of the organic EL layer is inverted, such that the first electrode is a cathode and the second electrode is an anode.

In each of the above embodiments, described as an example is the organic EL display device in which an electrode of a TFT connected to the first electrode is a drain electrode. The present invention can also be applied to an organic EL display device in which an electrode of a TFT connected to a first electrode is referred to as a source electrode. In each of the above embodiments, the organic EL display device is a display device. The present invention is also applicable to display devices including an active-matrix liquid crystal display device.

In each of the embodiments, the organic EL display device is exemplified as a display device. The present invention shall not be limited to organic EL display devices, and can be applied to flexible display devices. For example, the present invention can be applied to flexible display devices including quantum-dot light-emitting diodes (QLEDs); that is, light-emitting elements including layers containing quantum dots.

### INDUSTRIAL APPLICABILITY

As described above, the present invention is useful for a flexible display device.

### REFERENCE SIGNS LIST

B Folding Portion
Bc Intermediate Portion of Folding Portion (Picture-Frame Region and Back Face Slit) in Second Direction
Be Opposing End Portions of Folding Portion (Picture-Frame Region and Back Face Slit) in Second Direction
D Display Region
DP Display Panel
F Picture-Frame Region
Lc and Le Lengths of Back Face Slit (Lengths in Second Direction)
Ly Length of Picture-Frame Region between Opposing End Portions in Second Direction
P Subpixel
T Terminal Unit
U Back Face Slit
Ua and Ub Narrow Width Portions of Back Face Slit
V Slit (Front Face Slit) of Inorganic Insulating Film (At Least One Inorganic Insulating Film)
Wm and We Widths of Back Face Slit (Width in First Direction)
X First Direction
Y Second Direction
10 Resin Substrate (Base Substrate)
11 Base Coat Film (At Least One Inorganic Insulating Film)
13 Gate Insulating Film (At Least One Inorganic Insulating Film)
15 First Interlayer Insulating Film (At Least One Inorganic Insulating Film)
17 Second Interlayer Insulating Film (At Least One Inorganic Insulating Film)
20 Thin-Film Transistor (TFT) Layer
25 Organic EL Element (Light-Emitting Element)
30 Inorganic Multilayer Film (At Least One Inorganic Insulating Film)
31 Organic-EL-Element Layer (Light-Emitting Element Layer)
35 Sealing Film
40 Film
50a and 50b Organic EL Display Devices

1. A display device, comprising:
a display panel having
a display region,
a picture-frame region provided around the display region,
a terminal unit provided to one end portion of the picture-frame region in a first direction, and
a folding portion provided in the picture-frame region between the terminal unit and the display region, and extending in a second direction perpendicular to the first direction;
a film provided to a back face of the display panel and covering the back face; and
a back face slit shaped into a strip shape, provided to the film to overlap with the folding portion in a plan view, and extending to opposing end portions of the picture-frame region in the second direction,
wherein opposing end portions of the back face slit in the second direction are provided with a pair of narrow width portions each having a width narrower than a width in the first direction of an intermediate portion in the second direction.

2. The display device according to claim 1,
wherein a sum of lengths of the pair of narrow width portions in the second direction is shorter than a length between the opposing end portions of the picture-frame region in the second direction.

3. The display device according to claim 1,
wherein, outside the pair of narrow width portions in the first direction, the back face slit does not extend to the opposing end portions of the picture-frame region in the second direction.

4. The display device according to claim 1,
wherein the opposing end portions of the back face slit in the second direction are formed into a convex shape so that respective distal ends of the opposing end portions protrude in opposing directions along the second direction in a plan view.

5. The display device according to claim 1,
wherein the opposing end portions of the back face slit in the second direction are tapered so that respective distal ends of the opposing end portions protrude in opposing directions along the second direction in a plan view.

6. The display device according to claim 5,
wherein each of the opposing end portions of the back face slit in the second direction has a tapered portion formed stepwise in a plan view.

7. The display device according to claim 1,
wherein the display panel includes:
a base substrate;
a thin-film transistor layer having at least one inorganic insulating film provided on the base substrate; and
a front face slit shaped into a strip shape and provided to the inorganic insulating film to overlap with the folding portion in a plan view.

8. The display device according to claim 7,
wherein the front face slit overlaps with the back face slit in a plan view.

9. The display device according to claim 7, further comprising:
a light-emitting-element layer provided on the thin-film transistor layer and included in the display region; and
a sealing film provided to cover the light-emitting-element layer.

10. The display device according to claim 9,
wherein the light-emitting-element layer is an organic-electroluminescent-element layer. cm 11. A method for manufacturing a display device including:
a display panel having
a display region,
a picture-frame region provided around the display region,
a terminal unit provided to one end portion of the picture-frame region in a first direction, and
a folding portion provided in the picture-frame region between the terminal unit and the display region, and extending in a second direction perpendicular to the first direction;
a film provided to a back face of the display panel and covering the back surface; and
a back face slit shaped into a strip shape, provided to the film to overlap with the folding portion in a plan view, and extending to opposing end portions of the picture-frame region in the second direction, the method comprising:
a film attaching step of attaching the film to the back face of the display panel; and
after the film attaching step, a back-face-slit forming step of forming the back face slit by emitting a laser beam twice or more to the film in the folding portion in parallel with the second direction,
wherein, at the back-face-slit forming step, an emission distance or an emission time of the laser beam in the second direction is changed so that opposing end portions of the back face slit in the second direction are provided with a pair of narrow width portions each having a width narrower than a width in the first direction of an intermediate portion in the second direction.

12. The method for manufacturing the display device according to claim 11,
wherein, at the back-face-slit forming step, outside the pair of narrow width portions in the first direction, the back face slit is not formed up to the opposing end portions of the picture-frame region in the second direction.

13. The method for manufacturing the display device according to claim 11, further comprising
a thin-film-transistor-layer forming step of forming a thin-film transistor layer having at least one inorganic insulating film provided on the base substrate, the thin-film-transistor-layer forming step serving as a step of forming the display panel,
wherein, the thin-film-transistor-layer forming step includes forming a front face slit shaped into a strip shape and provided to the inorganic insulating film to overlap with the folding portion in a plan view.

14. The method for manufacturing the display device according to claim 13, further comprising:
a light-emitting-element-layer forming step of forming a light-emitting-element layer to be provided on the thin-film transistor layer and included in the display region; and
a sealing-film forming step of forming a sealing film to cover the light-emitting-element layer.

15. The method for manufacturing the display device according to claim 11, further comprising
a panel-outline-processing step of performing laser cut processing in which a laser beam is emitted to cut at least a portion of the display panel.
